(19) United States
(12) Patent Application Publication
(10) Pub. No.: US 2009/0114930 A1
(43) Pub. Date: May 7, 2009

(54) LIGHT-EMITTING DIODE AND LIGHT-EMITTING DIODE ARRAY LIGHT SOURCE

(75) Inventor: Cheng-Huang Kuo, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: National Central University, Taoyuan (TW)

(21) Appl. No.: 12/269,044

(22) Filed: Nov. 12, 2008

(30) Foreign Application Priority Data
Nov. 4, 2007 (TW) 96143029

(51) Int. Cl. H01L 33/00

(52) U.S. Cl. 257/88; 257/E33.001

(57) ABSTRACT

A light-emitting diode (LED) includes a substrate, a metallic buffer layer, a first type doped semiconductor layer, a light-emitting layer, a second type doped semiconductor layer, a first electrode, and a second electrode. The substrate has a plurality of bowl-shaped concaves or convexes on a surface thereof. The metallic buffer layer is disposed on the substrate and covers the bowl-shaped structure. The first type doped semiconductor layer is disposed on the metallic buffer layer. The light-emitting layer is disposed on a part of the first type doped semiconductor layer. The second type doped semiconductor layer is disposed on the light-emitting layer. The first electrode is disposed on the first type doped semiconductor layer not covered by the light-emitting layer. The second electrode is disposed on the second type doped semiconductor layer.

### CROSS-REFERENCE TO RELATED APPLICATION

This application claims the priority benefit of Taiwan application serial no. 96143029, filed on Nov. 14, 2007. The entirety of the above-mentioned patent application is hereby incorporated by reference herein and made a part of this specification.

### BACKGROUND OF THE INVENTION

1. Field of the Invention

The present invention generally relates to an LED, in particular, to an LED having a metallic buffer layer on a substrate with a plurality of bowl-shaped structures formed on a surface to achieve consistent directions of the emitted lights.

2. Description of Related Art

LEDs characterized by long service life and low power consumption are popularized, for example, in large-sized electronic bulletin boards, traffic lights, and directional lights. Currently, the LED industry aims at high luminance and low optical loss LEDs for replacing conventional illuminators. Moreover, at present, LEDs have been gradually applied in light sources of various apparatus, such as large-sized LED displays, LED illuminators, backlight modules of liquid crystal displays (LCDs), and projection apparatuses like digital light processing projectors (DLP projectors) and LCD projectors.

The LEDs are point light sources, so when applied in illuminators or backlight modules of LCDs, diffusers are usually disposed on a light-emitting section of the illuminators or backlight modules so as to achieve the effect of light uniformization. However, the addition of the diffusers may increase the manufacturing cost of the illuminators or backlight modules adopting the LEDs as the light sources. Therefore, it is a problem in need of solution for improving the uniformity of the light emitted from the LEDs so as to save the manufacturing cost of illuminators, backlight modules, or projectors using diffusers to achieve a better light uniformity.

### SUMMARY OF THE INVENTION

Accordingly, the present invention is directed to an LED, in which a plurality of bowl-shaped structures capable of converging light is formed on a surface of a substrate of the LED to achieve consistent directions of the emitted lights.

The present invention is also directed to an LED-array light source, which has a plurality of the above-LEDs, so as to provide an array light source for emitting parallel lights in consistent directions.

The present invention provides an LED, which includes a substrate, a metallic buffer layer, a first type doped semiconductor layer, a light-emitting layer, a second type doped semiconductor layer, a first electrode, and a second electrode. The substrate has a plurality of bowl-shaped concaves or convexes on a surface thereof. The metallic buffer layer is disposed on the substrate and covers the bowl-shaped structures. The first type doped semiconductor layer is disposed on the metallic buffer layer. The light-emitting layer is disposed on a part of the first type doped semiconductor layer. The second type doped semiconductor layer is disposed on the light-emitting layer. The first electrode is disposed on the first type doped semiconductor layer not covered by the light-emitting layer, and is electrically connected to the first type doped semiconductor layer. The second electrode is disposed on the second type doped semiconductor layer, and is electrically connected thereto. The first electrode is electrically insulated from the second electrode. In an embodiment of the present invention, a material of the substrate comprises silicon, glass, GaAs, GaN, AlGaAs, GaP, SiC, InP, BN, ZnO, AlO, LiAlO₂, or AlN.

In an embodiment of the present invention, the surface of each of the bowl-shaped structures is a spherical surface.

In an embodiment of the present invention, a material of the metallic buffer layer comprises Cr, Pt, Ni, or Pd.

In an embodiment of the present invention, the first type doped semiconductor layer is an n-type semiconductor layer, and the second type doped semiconductor layer is a p-type semiconductor layer.

In an embodiment of the present invention, the light-emitting layer includes a multiple quantum well (MQW) structure.

The present invention provides an LED-array light source, which includes a carrier and a plurality of LEDs disposed on the carrier. The connection between the components and elements of the LEDs is identical to the aforementioned LEDs, so the details will not be repeated herein again.

The LED of the present invention is mainly characterized in that a substrate has a plurality of bowl-shaped concaves or convexes on a surface thereof and a metallic buffer layer covering the bowl-shaped concaves or convexes. Thus, the lights generated from a light-emitting layer are reflected by the bowl-shaped structures and the metallic buffer layer after irradiated onto the surface of the substrate, and then exits from above the LED, so as to form the parallel lights in consistent directions. Further, the LED may also be applied in a LED-array light source to serve as a light source of the backlight module of the LCD, such that the backlight module is able to provide a better surface light source.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of an LED according to an embodiment of the present invention.

FIG. 2 is a schematic cross-sectional view of an LED according to another embodiment of the present invention.

FIG. 3 is a schematic cross-sectional view of an LED-array light source with a plurality of LEDs in FIG. 1.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

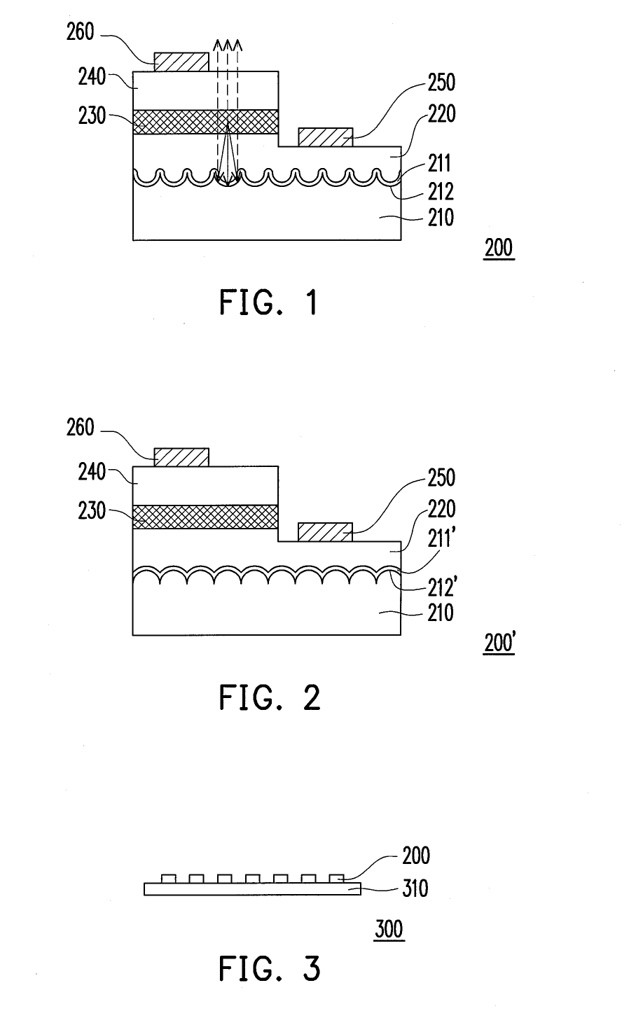

FIG. 1 is a schematic cross-sectional view of an LED according to an embodiment of the present invention. Referring to FIG. 1, the LED 200 of the present invention mainly includes a substrate 210, a metallic buffer layer 211, a first type doped semiconductor layer 220, a light-emitting layer 230, a second type doped semiconductor layer 240, a first electrode 250, and a second electrode 260. The elements and the connection relationship between the elements of the LED 200 would be illustrated in the following with the accompanying drawings.

The substrate 210 has a plurality of bowl-shaped concaves 212 on a surface thereof. As the surface of each of the bowl-shaped structures 212 is a spherical surface, the lights are reflected in parallel and consistent directions to be irradiated towards the above of the LED 200. The bowl-shaped structures 212 may be continuously or non-continuously arranged. The material of the substrate 210 comprises silicon, glass, GaAs, GaN, AlGaAs, GaP, SiC, InP, BN, ZnO, AlO, LiAlO₂, or AlN. The metallic buffer layer 211 is disposed on the substrate 210 and covers the bowl-shaped concaves 212. In this embodiment, the metallic buffer layer 211 is a metal layer. More particularly, the material of the metallic buffer layer 211 may include Cr, Pt, Ni, or Pd.

The first type doped semiconductor layer 220 is disposed on the metallic buffer layer 211. The light-emitting layer 230 is disposed on a part of the first type doped semiconductor layer 220. In an embodiment of the present invention, the light-emitting layer 230 is of an MQW structure. The second type doped semiconductor layer 240 is disposed on the light-emitting layer 230. In an embodiment of the present invention, the first type doped semiconductor layer 220 is an n-type semiconductor layer, and the second type doped semiconductor layer 240 is a p-type semiconductor layer. Further, the first type doped semiconductor layer 220, the light-emitting layer 230, and the second type doped semiconductor layer 240 are, for example, made of a III-V compound semiconductor material. For example, the matrix material of the first type doped semiconductor layer 220, the light-emitting layer 230, and the second type doped semiconductor layer 240 may be GaN, GaP, or AlInGaP.

The first electrode 250 is disposed on the first type doped semiconductor layer 220 not covered by the light-emitting layer 230, and is electrically connected to the first type doped semiconductor layer 220. The second electrode 260 is disposed on the second type doped semiconductor layer 240, and is electrically connected thereto. The first electrode 250 is electrically insulated from the second electrode 260.

As the substrate 210 of the LED 200 has a plurality of bowl-shaped concaves 212 on a surface thereof and metallic buffer layer 211, the lights produced by the light-emitting layer 230 are reflected by the bowl-shaped structures 212 and metallic buffer layer 211 covering the bowl-shaped concaves 212 after irradiated onto the surface of the substrate 210, and then exits from above the LED 200, so as to form the parallel lights in consistent directions.

FIG. 2 is a schematic cross-sectional view of an LED according to another embodiment of the present invention. Referring to FIG. 2, the LED 200′ is substantially the same as the LED 200 in FIG. 1, and only the difference is described. The substrate 210 of the LED 200′ has a plurality of bowl-shaped convexes 212′ on a surface thereof. Likewise, the surface of each of the bowl-shaped structures 212′ is a spherical surface, such that the lights are emitted in parallel and consistent directions towards above the LED 200′. Further, the bowl-shaped structures 212′ may be continuously or non-continuously arranged. Moreover, a metallic buffer layer 2111′ is disposed on the substrate 210 and covers the bowl-shaped convexes 212′. In this embodiment, the material of the metallic buffer layer 211′ is the same as that of the above metallic buffer layer 211 shown in FIG. 1.

The LEDs 200, 200′ may be applied in an LED-array light source to serve as the light source of the backlight module of the LCD. The application of the LED 200 in the backlight module is illustrated in the following embodiment. Referring to FIG. 3, the LED-array light source 300 mainly includes a carrier 310 and a plurality of LEDs 200 disposed on the carrier 310. The carrier 310 may be a printed circuit board (PCB) or a flexible printed circuit thin film. The LEDs 200 are illustrated in the above and not repeated herein. As the LEDs 200 of the present invention have a better effect of producing parallel light in consistent directions. Therefore, the LEDs 200 when serving as the light source of the backlight module enable the backlight module to provide a better backlight source. Moreover, the LED 200′ in FIG. 2 may also be applied in the backlight module 300 in FIG. 3 to achieve the same purpose.

In view of the above, the LED of the present invention is mainly characterized in that the substrate has a plurality of bowl-shaped concaves or convexes on a surface thereof and metallic buffer layer covering the bowl-shaped concaves or convexes. Thus, the lights produced by a light-emitting layer are reflected by the bowl-shaped structures and metallic buffer layer after irradiated onto the surface of the substrate, and then exits from above the LED, so as to form parallel lights in consistent directions.

In addition, the LED may also be applied to a LED-array light source to serve as the light source of the backlight module of the LCD, such that the backlight module is able to provide better light-emitting intensity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light-emitting diode (LED), comprising:
a substrate, having a plurality of bowl-shaped concaves or convexes on a surface thereof;
a metallic buffer layer, disposed on the substrate and covering the bowl-shaped concaves or convexes;
a first type doped semiconductor layer, disposed on the metallic buffer layer;
a light-emitting layer, disposed on a part of the first type doped semiconductor layer;
a second type doped semiconductor layer, disposed on the light-emitting layer;
a first electrode, disposed on the first type doped semiconductor layer not covered by the light-emitting layer, and electrically connected to the first type doped semiconductor layer; and
a second electrode, disposed on the second type doped semiconductor layer, and electrically connected to the second type doped semiconductor layer, wherein the first electrode is electrically insulated from the second electrode.

2. The LED according to claim 1, wherein a material of the substrate comprises silicon, glass, gallium arsenide (GaAs), gallium nitride (GaN), aluminum gallium arsenide (AlGaAs), gallium phosphide (GaP), silicon carbide (SiC), indium phosphide (InP), boron nitride (BN), zinc oxide (ZnO), aluminium oxide (AlO), lithium aluminate (LiAlO₂), or aluminium nitride (AlN).

3. The LED according to claim 1, wherein a surface of each of the bowl-shaped concaves or convexes is a spherical surface.

4. The LED according to claim 1, wherein a material of the metallic buffer layer comprises Cr, Pt, Ni, or Pd.

5. The LED according to claim 1, wherein the first type doped semiconductor layer is an n-type semiconductor layer, and the second type doped semiconductor layer is a p-type semiconductor layer.

6. The LED according to claim 1, wherein the light-emitting layer comprises a multiple quantum well (MQW) structure.

7. An LED-array light source, comprising:
a carrier; and
a plurality of LEDs, disposed on the carrier, and each of the LEDs comprising:
a substrate, having a plurality of bowl-shaped concaves or convexes on a surface thereof;
a metallic buffer layer, disposed on the substrate and covering the bowl-shaped concaves or convexes;
a first type doped semiconductor layer, disposed on the metallic buffer layer;
a light-emitting layer, disposed on a part of the first type doped semiconductor layer;
a second type doped semiconductor layer, disposed on the light-emitting layer;
a first electrode, disposed on the first type doped semiconductor layer not covered by the light-emitting layer, and electrically connected to the first type doped semiconductor layer; and
a second electrode, disposed on the second type doped semiconductor layer, and electrically connected to the second type doped semiconductor layer, wherein the first electrode is electrically insulated from the second electrode.

8. The LED-array light source according to claim 7, wherein the carrier comprises a printed circuit board (PCB) or a flexible printed circuit thin film.

9. The LED-array light source according to claim 7, wherein a material of the substrate comprises silicon, glass, GaAs, GaN, AlGaAs, GaP, SiC, InP, BN, ZnO, AlO, LiAlO₂, or AlN.

10. The LED-array light source according to claim 7, wherein a surface of each of the bowl-shaped concaves or convexes is a spherical surface.

11. The LED-array light source according to claim 7, wherein the first type doped semiconductor layer is an n-type semiconductor layer, and the second type doped semiconductor layer is a p-type semiconductor layer.

12. The LED-array light source according to claim 7, wherein the light-emitting layer comprises an MQW structure.
